(19) United States
(12) Patent Application Publication
(10) Pub. No.: US 2026/0269280 A1
(43) Pub. Date: Sep. 10, 2026

(54) PART COATED WITH A CARBON-BASED LAYER

(71) Applicant: HYDROMECANIQUE ET FROTTEMENT, ANDREZIEUX-BOUTHEON (FR)

(72) Inventors: Michael OUGIER, SAINT CHAMOND (FR); Marie-Alix LEROY, SAINT-ETIENNE (FR)

(21) Appl. No.: 19/162,402

(22) PCT Filed: Mar. 11, 2024
(86) PCT No.: PCT/FR2024/050293

§ 371 Date: Sep. 5, 2025

(30) Foreign Application Priority Data
Mar. 15, 2023 (FR) 2302416

(51) Int. Cl. H01M 8/0228; C23C 14/06; C23C 14/24; H01M 8/0208; H01M 8/0213; H01M 8/0215

(52) U.S. Cl. CPC H01M 8/0228; C23C 14/0605; C23C 14/24; H01M 8/0208; H01M 8/0213; H01M 8/0215

(57) ABSTRACT

A part includes comprising a metal substrate and a layer of amorphous carbon-based material having sp2 hybridised bonds and sp3 hybridised bonds. The layer has
a first content of sp3 hybridised bonds on the substrate side, and
a second content of sp3 hybridised bonds on the side of an external surface of the layer,
the first content being greater than the second content.

An average content within the layer of sp3 hybridised bonds is between 5% and 65%

and in that the content of sp3 hybridised bonds evolves continuously within the layer.

### TECHNICAL FIELD

The invention relates to the technical field of coatings for fuel cell or electrolyser electrodes.

### PRIOR ART

The invention relates to electrochemical systems, such as fuel cells and electrolysers, and in particular to proton exchange membrane fuel cells (PEMFC).

The operation of these electrochemical systems involves an acidic or basic environment, oxidising at the cathode, a temperature which can be from 60 to 160° C., and the optional presence of halides. This environment promotes the corrosion of the elements of said system, such as interconnection plates, also called electrodes, interconnectors or bipolar or monopolar plates.

In particular, bipolar plates are one of the critical components for the durability of these systems: they consist of metal sheets, the thickness of which is around 100 μm. They must be protected by a coating in order to preserve sufficient surface electrical conduction, to minimise electrical losses at the interfaces, and in order to avoid the corrosion of the metal sheets in the aggressive medium of the cell.

The surface conduction of a bipolar plate made of a metal material, including in a corrosive medium, is generally obtained by the deposition of a carbon- or gold-based functional layer on the extreme surface of a substrate. In the case of carbon layers, the prior deposition of an underlayer on the substrate can improve the adhesion of the functional layer and ensure the mechanical strength of the stack.

Generally, the adhesion between the layer and the substrate, as well as the mechanical strength of the functional layer, which is reflected in an absence of damage by cracking or by delamination, are important parameters.

Indeed, the barrier function of this layer must not be degraded over the operating duration of the electrochemical system, so as to protect the metallic substrate from oxidation, in order to prevent the emission of metal cations from the substrate into the medium of the cell, even in small amounts.

Local and generally temporary variations in the conditions of the electromechanical system increasingly stress the functional layer, within which defects such as deficits, cracks, holes, intercolumn gaps, can cause a rapid degradation of the substrate, in particular by galvanic coupling with the functional layer.

Furthermore, when the membrane of the cell is made of fluoropolymer, it can release fluoride ions F-which, inter alia, promote corrosion by pitting of the stainless steel substrates. This can then lead to a rapid and catastrophic failure of the entire cell.

In order to protect a cell from such failures and while meeting the aims of mechanical strength and electrical conduction described above, it is known from the prior art to deposit a functional layer, in particular a carbon-based functional layer.

The physical vapour deposition (PVD) of carbon is characterised by the possibility of obtaining a wide range of materials with properties which can differ widely, including when there is only carbon deposition; for example, by adjusting the proportions of sp2 hybridised atoms relative to sp3 hybridised atoms, it is possible to obtain usage properties which are very different from one another.

In order to improve the features of the deposited layer, additional energy is generally provided during the deposition. It is also possible to place larger or smaller proportions of hydrogen within the carbon layer.

Good performance has been obtained by adding other elements to the carbon. Thus, document WO2011077755 describes a bipolar plate for a fuel cell coated with a carbon-based functional layer, doped with nitrogen at a content of between 3 and 20 at %, and with hydrogen at a content of greater than 0% and less than or equal to 20 at %.

Document WO2007136131 describes a conductive member provided with an amorphous carbon layer, doped with silicon at a content of less than 1 at %, and containing hydrogen at a maximum content of 30 at %.

Document WO2013114836 describes an amorphous carbon layer containing hydrogen, nitrogen and oxygen at maximum contents of 30, 20 and 3 at %.

However, controlling the contents of additional elements complicates the method and makes the treatment more expensive.

Document JP6512577 describes a coating comprising two distinct layers of amorphous carbon of different types, and applications PCT/FR2022/051631 and PCT/FR2022/051642 in the name of the Applicant provide solutions that make it possible to meet the requirements of the United States Department of Energy (DOE). However, the service life of some coatings can be further improved, in particular at high potential or at high temperature.

Finally, one difficulty lies in the contradiction between having the thinnest layer possible in order for its deposition to be rapid, and the lower durability that a thin layer has, meaning it will be degraded more quickly.

One aim of the invention is therefore to overcome the disadvantages described above.

### DISCLOSURE OF THE INVENTION

To this end, the invention first aims to propose a carbon coating, the intrinsic characteristics of which are optimal in order to ensure a high performance for electrodes, for example, of fuel cells.

Another aim of the invention is to propose a carbon coating, the intrinsic characteristics of which are compatible with reversible systems (Unitised Regenerative Fuel Cell or URFC), which operate at a higher potential than PEMFCs, or for components of fuel cells operating at high temperature (HT PEMFC), which operate between 12° and 200° C.

The invention also relates to a part which is suitable for particular applications of fuel cells and is efficient and inexpensive.

The invention also relates to a deposition method, making it possible to obtain such a carbon coating.

To this end, a part has been developed, comprising a metal substrate and a layer of amorphous carbon-based material having sp2 hybridised atoms and sp3 hybridised atoms, the layer having:
a first content of sp3 hybridised atoms on the substrate side, and
a second content of sp3 hybridised atoms on the side of an external surface of the layer, which second content is lower than the first content.

According to the invention, an average content within the layer of sp3 hybridised bonds is between 5% and 65%, and preferably between 5% and 45%, and the content of sp3 hybridised bonds evolves continuously within the layer. There is a gradient of the content from the substrate towards the external surface. Conversely, the content of sp2 hybridised atoms exhibits the reverse gradient within the layer (the sum of the sp2 and sp3 contents is 100%).

In this way, the layer of carbon-based material has the optimal intrinsic characteristics to ensure high performance for electrodes. The higher content of sp3 hybridised atoms makes it possible to benefit, on the substrate side, from the advantages of the sp3 form of carbon, namely its good resistance to oxidation and degradation while avoiding the disadvantage, on the external surface side, of the high resistivity of the sp3 form of carbon by virtue of a higher content of sp2 bonds.

The part according to the invention therefore has an excellent service life by virtue of the resistance of the sp3 form, while having a low interfacial contact resistance and good surface conductivity by virtue of the sp2 form of carbon.

Because the evolution in the content of sp3 hybridised atoms within the layer is continuous, neither the distribution of internal stresses nor the Young's modulus within the carbon layer exhibit any discontinuity, or interface, which would be sources of preferential degradation, leading for example to flaking or delamination.

The cohesion of the carbon layer is therefore improved, which contributes to the durability of the part, in particular by increasing its resistance to transient phenomena.

In the specific case of use within a fuel cell, the part forms part of a plate of the monopolar or bipolar type for a fuel cell. In this case, the part meets the requirements of the DOE.

The average content of sp3 hybridised atoms is measured by Raman spectrometry at several excitation wavelengths of the laser (325 nm, 442 nm, 488 nm, 633 nm). The power of the laser is limited in order to avoid modification of the material under irradiation. The intensity spectra as a function of the Raman shift are adjusted by two Gaussians for the G (elongation mode) and D (vibration mode) peaks of the carbon bonds. Plotting the position of the G peak (in Raman shift) as a function of the wavelength provides a straight line, the gradient of which is the dispersion of the G peak (in cm⁻¹/nm). This dispersion is proportional to the sp3 content of the analysed material. A chart can be found, for example, in the article “Structure of diamondlike carbon films deposited by femtosecond and nanosecond pulsed laser ablation” by Sikora et al., Journal of Applied Physics 108, 113516 (2010).

The local content of sp3 hybridised atoms can be determined by virtue of the local density of the material constituting the layer (C). This can be measured by transmission electron microscopy (TEM), on cross sections using the electron energy loss spectroscopy (EELS) technique, and spatially resolved with electron beam sizes limited to a fraction of a nanometre. There is a proportional relationship between the density of the layer and the content of sp3 hybridised atoms (see for example the publication “Diamond-Like Amorphous Carbon” by J. Robertson, in Materials Science and Engineering, R 37 (2002) 129-281, FIG. 32).

According to another characteristic, independent of the characteristics underlying the invention, or else in combination with the preceding characteristics, carbon is implanted in a material receiving the layer, whether this is the material of the substrate or the material of an underlayer. This implantation is obtained during the deposition of the layer, and advantageously contributes to the adhesion of the layer to its support. Surprisingly, the Applicant has found that the implantation of carbon during an initial phase of the deposition provides the part with excellent properties with regard to the aforementioned requirements.

In other words, it could very well be envisaged to provide a part comprising a metal substrate and a layer of amorphous carbon-based material having sp2 hybridised atoms and sp3 hybridised atoms, the layer having:
a first content of sp3 hybridised atoms on the substrate side, and
a second content of sp3 hybridised atoms on the side of an external surface of the layer, which second content is lower than the first content;
wherein carbon is implanted in a material receiving the layer, whether this is the material of the substrate or the material of an underlayer, the implantation of the carbon being obtained during the deposition of the layer;
without being concerned with the average content of sp3/sp2 hybridised bonds within the layer.

In a preferred embodiment, the part comprises a single layer of carbon-based material. The method for producing the part comprises only a single carbon deposition step. It is therefore simplified, and the cost of the part is reduced. Even more preferentially, the part comprises a single layer of material consisting solely of carbon.

In order to promote the conductivity of the part, the average content of sp3 hybridised bonds is limited. The average content of sp3 hybridised bonds within the layer is therefore between 10% and 45%. Preferably, the average content of sp3 hybridised bonds within the layer is between 10% and 30%. In some embodiments, the material forms a thin layer commonly referred to as “a-C”. Preferentially, the content of sp3 hybridised bonds is homogeneous within the layer and is not localised by means of clusters of crystals having a high content of sp3 hybridised bonds, forming a carbon layer which has a heterogeneous content of sp3 hybridised bonds.

To reduce the production cost of the part, the carbon-based material is free of metal dopants. In addition, the dopants form carbides within the carbon layer, and these local carbides constitute preferential defect sites and corrosion sites. During the deposition with a dopant, metal droplets can also form and constitute preferential corrosion sites. Such disadvantages are avoided.

The best performance in terms of durability, in particular at high potential, was obtained with layers of carbon-based material free of nitrogen and hydrogen.

“Free of hydrogen and nitrogen” and “free of dopants” means that these elements are not intentionally added in the deposited layer and can only be present in a quantity insufficient to give particular properties to the deposited layer. Preferably, these elements are only present as traces.

Advantageously, the layer has a thickness of greater than or equal to 20 nm, preferably between 20 nm and 250 nm, more preferentially between 50 nm and 150 nm, even more preferentially between 60 nm and 100 nm.

To improve the adhesion of the layer to the part and to protect the substrate from potential oxidation, the part comprises an underlayer which is located between the substrate and the layer of carbon-based material and is in contact with the layer.

Advantageously, the material of the underlayer is selected from chromium, titanium, zirconium, tantalum, niobium, or the alloys thereof and the nitrides and carbides thereof, or the material of the underlayer is a ceramic. Preferably, the underlayer is an electrically conductive material which passivates when subjected to oxidation. Titanium is a preferred material.

In order to have a favourable compromise between the duration of deposition of the metal underlayer and the improvement in the adhesion afforded thereby, the thickness thereof is between 5 nm and 100 nm, preferably between 20 nm and 40 nm, and is for example 50 nm.

In a particular embodiment suitable for the field of fuel cells, the substrate comprises a stainless steel, titanium, a titanium alloy, or a nickel-, chromium- and iron-based alloy, which is preferably an Inconel®.

Preferably, the substrate is a plate having a thickness of between 10 μm and 1000 μm.

Preferably, such a part forms part of a plate of the monopolar or bipolar type for a fuel cell, as it has the technical characteristics that ensure it has sufficient durability and performance to satisfy the requirements in the field of fuel cells.

The invention also relates to a method for the vacuum vapour deposition of a layer of a material based on amorphous carbon on a substrate, which method is noteworthy in that a parameter influencing the ratio of sp2 or sp3 hybridised bonds in the carbon varies continuously during the deposition of the layer such that it has:
a first content of sp3 hybridised bonds on the substrate side, and
a second content of sp3 hybridised bonds on the side of an external surface of the layer, which second content is lower than the first content,
   and in that an average content within the layer of sp3 hybridised bonds is between 5% and 65%, and preferably between 5% and 45%,
   and in that the content of sp3 hybridised bonds evolves continuously within the layer.

“Varies continuously” means that the parameter does not have any discontinuities during the deposition, such as during the deposition of successive distinct layers, each having a different sp3 hybridised bond content. It may nevertheless exhibit strictly increasing or decreasing variations, or variations that are not strictly increasing or decreasing (oscillations for example).

### BRIEF DESCRIPTION OF THE DRAWINGS

FIG. 1 is a diagram of a section of a part according to the invention.

FIG. 2 is a graph illustrating the variation in the content of carbon atoms in sp3 hybridised form within a layer of carbon-based material of such a part.

FIG. 3 is a graph illustrating the variation in content in another part according to the invention.

FIG. 4 is a graph illustrating the variation in content in another part according to the invention.

FIG. 5 is a graph illustrating the variation in content in another part according to the invention.

FIG. 6 is a graph illustrating the variation in content in another part according to the invention.

FIG. 7 is a graph illustrating the corrosion current density during a test.

FIG. 8 is a graph illustrating the corrosion current density during another test.

FIG. 9 is a graph illustrating the corrosion current density during another test.

### DETAILED DESCRIPTION OF THE INVENTION

Several types of technologies exist in the field of vacuum depositions, and each has its advantages and its disadvantages. In the context of treating parts (P), and in particular monopolar or bipolar plates for fuel cells, the Applicant has sought to optimise known deposition methods.

The Applicant performed various series of tests and interpretations aimed at obtaining a deposit of a carbon-based material which forms a layer (C) on a substrate(S) and has good properties, in particular of mechanical strength, corrosion resistance, adhesion, and electrical conduction.

The deposition is preferably carried out by cathodic arc. In this embodiment, the facility used to implement one embodiment of the method comprises a secondary vacuum enclosure equipped with a pumping system, a plasma source, an arc spray source, and a substrate holder on which the substrate or substrates(S) to be treated are mounted.

The pumping system makes it possible to obtain a secondary vacuum in the chamber, i.e. a pressure of an order of magnitude of between 10⁻⁷ mbar and 5×10⁻⁵ mbar. The pumping system, or another independent system, is capable of introducing a gas into the vacuum chamber. The gas is intended to be ionised, and is preferentially argon.

The arc spray source is conventional, and is supplied continuously. Alternatively, the supply may be of the pulsed type. Electrical discharges on a graphite target generate carbon ions. The arc supply may be ignited intermittently (e.g. 60 s ignition and 10 s extinguishing).

The substrate carrier is polarised, i.e. a negative voltage or potential difference is applied at its terminals in order to create a flow of carbon ions in the direction of the substrate carrier. This acceleration of ions occurs in the vicinity of the substrates(S) since the electrical field which results from the polarisation of the parts (P) extends over a short distance of the order of a few millimetres.

In the case of the polarisation of a substrate(S) in a plasma, the polarisation voltage is applied between the substrates(S) and the ground of the facility. A potential difference is established between the substrates(S) and the plasma. It is in this potential drop zone, over approximately 0.5 to 2 mm from the surface of the substrates(S), that the ions are accelerated.

Various tests are carried out within the facility by modifying the parameters of the thickness of the layer (C), the presence or absence of an underlayer (SC) between the substrate(S) and the layer (C), the polarisation voltage (the value thereof, the continuous or pulsed mode of application thereof, and the duty cycle in the case of a pulsed voltage), the source ignition current (value of the current, or duty cycle of the intermittency).

The parts (P) are coated with a functional layer (C) of carbon-based material, intended to protect the substrate(S) from oxidation in order to ensure the service life of the part (P), while having a low interfacial contact resistance in order to ensure the performance of a cell or of an electrolyser comprising the part (P).

The service life of the layer (C) is evaluated by subjecting it to an electrochemical corrosion test.

Under the normal operating conditions of a cell, the potential at the cathode is less than 0.9 V compared to a normal hydrogen electrode, “NHE” (notation 0.9 V/NHE). Nevertheless, under accidental and transient conditions, the electrode could be subjected to higher potentials, up to 1.6 V/NHE.

This is particularly the case when the cell is started up or when the cell is stopped, during which the presence of H2/air or H2/O2 fronts on a plate can generate reverse current phenomena: the powered part of the cell discharges into the unpowered part of the cell, generating very high potentials locally (electrolysis conditions).

These transient phenomena can last longer if the cell was poorly drained after it was stopped (presence of residual water) and if the ambient temperature is very low: distribution channels can be blocked by ice from the residual water, which delays the filling and homogenisation of the compartment.

It is therefore necessary for the interconnection plates to be able to withstand very high potentials, over periods of several hours, relative to the service life of the cell. This is all the more important for cells for heavy goods vehicles.

The electrochemical tests performed by the Applicant are therefore more stringent compared to the requirements of the DOE, and take place in an acidic solution with a pH equal to 3, at 80° C. and with 0.1 ppm of fluoride ion. This test medium is defined by the DOE in the United States of America to simulate the operating environment of a PEMFC. In the context of the present tests, the potential is set at +1.6 V/NHE on the working electrode on which the material to be tested is mounted. The potential used is greater than is recommended by the DOE (0.8 V/NHE) in order to make the test more stringent and to only select the best deposits which can withstand accidental conditions. The addition of air bubbling makes it possible to simulate the cathode compartment of a fuel cell. The test is performed for a duration of 20 hours.

The corrosion current is an image of the rate of degradation of a part (P) comprising a substrate(S) having received a layer (C) of material. Indeed, the higher the corrosion current, the more the part (P) is in the process of being oxidised, i.e. the layer (C) of material is poorly fulfilling its protective role. In practice, a corrosion current density of less than 2000 nA/cm² after 20 hours under a potential of 1.6 V/NHE is considered acceptable.

The surface conductivity of the coating is evaluated by measuring its interfacial contact resistance or “ICR”. A coating having good surface conductivity has a low ICR, for example less than 10 mΩ·cm².

The ICR is measured on a stack composed of a block of copper-carbon sheet (GDL—Gas Diffusion Layer)-deposit-nickel paint-copper block, to which a current is applied of 100 mA for a surface area of 1 cm², then the resistance of the assembly is calculated from the voltage measured.

This stack is representative of the contact between a coated bipolar plate and the gas diffusion layer (C). A pressure of 138 N/cm² is applied thereto by a lever arm system with weights, this pressure being representative of the pressure applied to an electrochemical cell during its assembly.

The resistance Rₜₒₜₐₗ obtained is the sum of the equation:
of the resistance of the Cu—Cu system
of one times the copper carbon interfacial contact resistance R_{Cu/C}
of one times the carbon felt resistance RC
of the interfacial contact resistance between the deposit and the carbon R_{C/deposit}.
of the linear resistance of the deposit R_{deposit}.
of the resistance of the 316L steel plate R_{316L}
of one times the nickel copper interfacial contact resistance R_{Ni/Cu}

$$[ Math . 1 ]$$

$${R}_{total} = {R}_{offset} + {R}_{Cu / C} + {R}_{C / deposit} + {R}_{deposit} + {R}_{Ni / Cu} \qquad ( 1 )$$

The ICR is determined using the following equation.

$$[ Math . 2 ]$$

$${R}_{C / deposit} + {R}_{deposit} = RCI = {R}_{total} - {R}_{offset} - {R}_{Cu / C} - {R}_{Ni / Cu} \qquad ( 2 )$$

It is relevant to look at the ICR after the more stringent corrosion test described above. Indeed, a substrate(S) coated with a metal underlayer (SC) then a carbon layer (C) may have good corrosion resistance, but this can sometimes be explained by a passivation of the material of the underlayer (SC) in the case of degradation of the carbon layer (C). However, this passivated material is not sufficiently conductive on the surface, meaning that a bipolar plate functionalised with such a deposit protects a fuel cell from an accidental degradation, but the performance of this fuel cell would be reduced. It is therefore necessary to consider these two parameters cumulatively.

The passivated underlayer ensures that the stainless steel of the substrate(S) will not emit metal cations into the electrochemical system.

Another criterion is the visual appearance of the layer (C), which must not have been macroscopically damaged, consumed or delaminated at the end of the test.

Several series of tests were performed within the facility. The parts (P) tested are test specimens for which the substrate(S) is made of 316L stainless steel and which are intended to be coated on both of their faces, in order to simulate the coating of bipolar plates.

The substrate(S) is positioned on a mount and is cleaned and blown in order to remove contaminants and dust which may be present on its surface. It is then introduced into a vacuum deposition facility.

The pumping system is activated, such that the pressure in the chamber is less than 5×10⁻⁶ mbar, and the chamber (10) is heated to remove the water adsorbed on its walls.

The surfaces of the substrate(S) to be coated are heated and then bombarded with argon ions in order to eliminate the water adsorbed on these surfaces and to pickle a layer (C) of oxide present on the surface.

The pumping system then adjusts the flow rate of argon into the chamber so that an argon pressure of approximately 2×10⁻⁴ mbar prevails during the deposition phase. Argon is used in order to be ionised, and is not intended to be contained in the carbon-based layer (C).

It is not sought to perform a reactive deposition of the layer (C): the pumping system does not introduce nitrogen or other addition elements into the chamber, such as dopants: the internal volume of the chamber, and therefore the deposited layer (C), are free of nitrogen or other addition elements.

The layer (C) does not contain hydrogen, nitrogen, or any other dopant such as tungsten. In the technical field in question, “does not contain” means a zero content or a content as a trace, or at the very least a content of less than 1 at %. In any case, it is sought to obtain a sufficiently low quantity of these elements so that they cannot confer properties on the deposited layer (C). None of these elements are intentionally added during the deposition.

However, despite the heating performed, a little adsorbed water still remains within the chamber: in practice, at the vacuum pressures of around 10⁻⁵ mbar implemented, there is virtually only steam remaining within the chamber, as long as said chamber does not contain any notable leaks. It is therefore not possible to avoid the presence of oxygen in the chamber, via water, and this component can be found in the deposit during its formation. Oxygen can also be contained in the carbon-based target, as the graphite target is generally porous.

Unlike hydrogen, oxygen is not readily removed from the layer (C) during its deposition, and its content depends on the ionic bombardment conditions applied, which themselves are specific to the method used. Only oxygen can therefore be present in the layer (C), with the exception, of course, of atoms from the inert gas (argon) which can be present in minimal amounts.

An underlayer (SC) of metal material may optionally be deposited on the substrate(S), for example by cathode sputtering of a target corresponding to the desired material (metal or ceramic, optionally within a reactive atmosphere to modify the composition of the underlayer (SC) only).

Next, a layer of carbon-based material is formed from a graphite target by arc deposition.

A first series of tests is performed by modifying:
the value of the polarisation voltage (whether continuous or pulsed);
if applicable, the duty cycle of the polarisation voltage;
the duty cycle of the intermittency of the ignition of the graphite target (arc ignition).

All of the samples tested have a 50 nm-thick titanium underlayer (SC) and a 70 nm-thick carbon layer (C).

The parts (P) were then characterised in order to differentiate between the different deposits obtained.

After the tests performed, the Applicant found that, despite the preconception, for example described in the documents WO2022049245A1 and WO202128399A1, that a high content of sp3 hybridised form would be more protective, some of the samples rich in sp3 bonds (56% sp3) exhibit a high corrosion current and also a large increase in the ICR after corrosion testing: merely the criterion of the average content of sp3 bonds does not appear to be sufficient to differentiate between the parts (P) obtained.

Moreover, parts (P) having moderate sp3 contents have very different characteristics: a sample comprising on average 20% of sp3 bonds may be non-compliant, whereas a sample comprising 45% thereof is.

Unexpectedly, the presence of oxygen within the layer (C) is not a decisive criterion.

In a first embodiment, the content of sp3 bonds evolves continuously within the layer (C), according to a gradient that decreases from the substrate(S) to the external surface (SE). This characteristic explains why the sample having an average sp3 bond content of 45% is compliant, whereas the samples having average contents of 20% and 56% are not.

In practice:
when deposition starts, the sp3 content is high (i.e. on the substrate(S) side);
during deposition, the sp3 content decreases gradually, without discontinuity;
at the end of deposition, the sp3 content is lower (i.e. on the external surface (SE) side of the part (P)).

In another embodiment, the gradient strictly decreases from the substrate(S) towards the external surface (SE). The term “strictly decreases” means that the sp3 bond content never increases. However the content may plateau. In this embodiment, the first content (sp3% 1h) is equal to the maximum sp3 content (sp3% max) within the layer (C), and the second content (sp3% 2b) is the minimum sp3 content (sp3% min).

In another embodiment, the content of sp3 bonds exhibits oscillations, such that it increases over at least a portion of the layer, depending on the variations in the influencing parameter. In this embodiment, the first content (sp3% 1h) is not the maximum sp3 content (sp3% max) within the layer (C), and the second content (sp3% 2b) is not the minimum content (sp3% min).

In both cases, the content of sp3 bonds exhibits an overall downward trend within the layer (C). Indeed, a higher content of sp3 bonds at the external surface would imply too high an ICR, and too high a content of sp2 bonds at the substrate would imply poor corrosion resistance.

The variation in the level of sp3 hybridisation modifies the characteristics of the layer (C). It is known that a carbon layer comprising between 10% and 35% of sp3 bonds (the remainder being sp2) belongs to the “a-C” family of amorphous carbon layers, whereas a carbon layer comprising between 60% and 85% sp3 belongs to the “ta-C” family of tetrahedrally-bonded carbon layers, and that within the “ta-C” family of tetrahedrally-bonded carbon layers, a carbon layer comprising 65% of sp3 bonds does not have the same characteristics (mechanical, electrical) as a carbon layer comprising 85% of sp3.

The content of sp3 bonds in a material therefore confers a particular nature on this material, and varying the content of sp3 bonds within the layer (C) makes it possible to obtain several natures of materials within the layer.

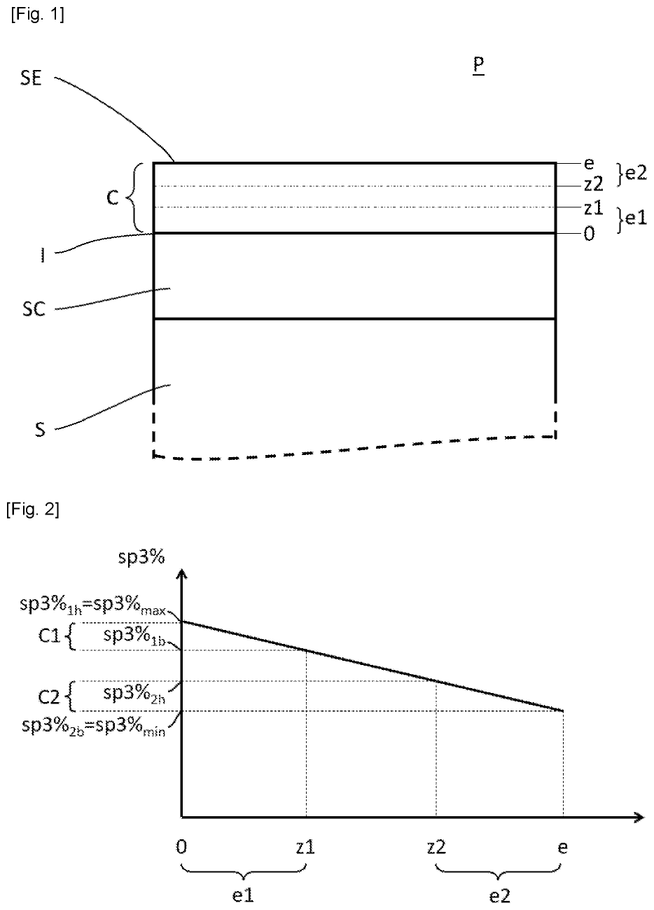

Referring to FIG. 1, the part (P) has, within the carbon layer (C):
a first zone (e1) on the substrate(S) side which is rich in sp3 bonds and within which a first composition (C1) of the layer (C) is predominantly present;
a second zone (e2) on the external surface (SE) side which is less rich in sp3 bonds and within which a second composition (C2) of the layer (C) is predominantly present;
the first zone (e1) and the second zone (e2) being separated by an intermediate zone considered to be negligible with regard to the invention.

The first composition corresponds to an sp3 bond content greater than a first threshold (sp3% 1b), or to an sp3 bond content between a first threshold (sp3% 1b) and the first content (sp3% 1h).

The second composition corresponds to an sp3 bond content lower than a second threshold (sp3% 2h), or to an sp3 bond content between the second content (sp3% 2b) and a second threshold (sp3% 2h).

The first composition (C1) is for example defined by a first threshold (sp3% 1b) of the sp3 bond content of greater than 80%, or 75%, or 70%, or 65%, or 60%, or 55%, or 50%, or 45%, or 40%, or 35%, or 30%, or 25%, or 20%, or 15%.

The second composition (C2) is for example defined by a second threshold (sp3% 2h) of the sp3 bond content which is lower than that of the first composition (C1) and for example lower than 4%, or 5%, or 10%, or 15%, or 20%, or 25%, or 30%, or 35%, or 40%, or 45%, or 50%, or 55%, or 60%.

Depending on the values adopted for the first composition and for the second composition, the first zone (e1) and/or the second zone (e2) each measure between 1 nm and 30 nm, or between 5 nm and 15 nm, or between 7 nm and 10 nm.

The first zone (e1) which is rich in sp3 bonds has good mechanical characteristics and characteristics of resistance to oxidation.

The second zone (e2) which is less rich in sp3 bonds has the advantage of having better electrical conductivity, and therefore implies a decrease in the ICR.

The combination of these two zones within the same layer (C) therefore makes it possible to combine the advantages of each of the natures of deposit. It is possible to produce layers having lesser thicknesses than those of the prior art, for equivalent performance according to the requirements of the DOE, or even greater than the requirements of the DOE since the invention provides reinforced resistance at high potential.

A lesser thickness, in addition to a shorter deposition time, also provides better resistance to deformation. If the layer (C) is deposited on a flat part and is then shaped (creation of channels in the bipolar plate), the part (P) is less likely to have defects such as cracks or delaminations after shaping by virtue of its low thickness and by virtue of the presence of an sp3-rich layer near the interface (I) between the layer (C) and the material receiving it.

Furthermore, the continuous variation in the sp3 bond content improves the durability of the layer. The absence of discontinuity:
enables better distribution of the internal stresses of the carbon layer (C), and thus avoids flaking phenomena;
enables better cohesion of the material within the layer (C), and thus avoids the presence of preferential sites for corrosion attacks.

The variation in the sp3 bond content is obtained by modifying an influencing parameter during deposition. For example, the influencing parameter may be the value of the polarisation voltage, whether it is continuous or pulsed:
it is possible to begin the deposition of the layer (C) with a suitable polarisation voltage such that the carbon ions being deposited are deposited on the part (P) with a lot of energy, thereby promoting sp3 hybridisation.
during deposition, the polarisation voltage is gradually decreased such that the impact energy of the ions also gradually decreases. Sp3 hybridisation becomes increasingly less favoured, and therefore the content thereof gradually decreases.

The influencing parameter is chosen on the basis of the deposition method implemented, the criterion being the continuous variation in the quantity of energy supplied during the deposition. For example, in the case of high power impulse magnetron sputtering (HiPIMS), the influencing parameter may be the amount of ions generated by the plasma source, which depends on the pulse parameters.

Alternatively, the influencing parameter may be the arc current applied to the cathode, or the ignition ratio of a pulsed polarisation. In the case of a pulsed polarisation voltage, it is recalled that, for a given average value, the substrate holder is supplied with a voltage which is inversely proportional to the ignition duration. For example:
for an average voltage of 100 V and an ignition ratio of 50%, the substrate holder(S) can be at 0 V half the time and at 200 V the other half (average of 100 V);
for an average voltage of 100 V and an ignition ratio of 25%, the substrate holder(S) can be at 0 V three quarters of the time and at 400 V a quarter of the time (average of 100 V).

Although the average voltage is identical, it is observed that significant differences in the instantaneous voltage modify the supply of energy to the carbon ions during the deposition of the layer (C).

By adapting the variation in the influencing parameter (linear or not), it is possible to obtain different gradient profiles.

FIGS. 2 to 4 show three different gradient profiles of the sp3 content (sp3%) on the basis of the position within the thickness (e) of the layer (C). On the basis of the content variation profile, the layer (C) will comprise a first zone (e1) and a second zone (e2) of variable thicknesses. The first zone (e1) extends from the interface (I) between the layer (C) and the material receiving it, and a first depth (z1), the second zone (e2) extends between a second depth (z2) and the external surface (SE).

FIG. 2 illustrates a first example in which the sp3 bond content decreases regularly. The first zone (e1) and the second zone (e2) are then of equal thickness.

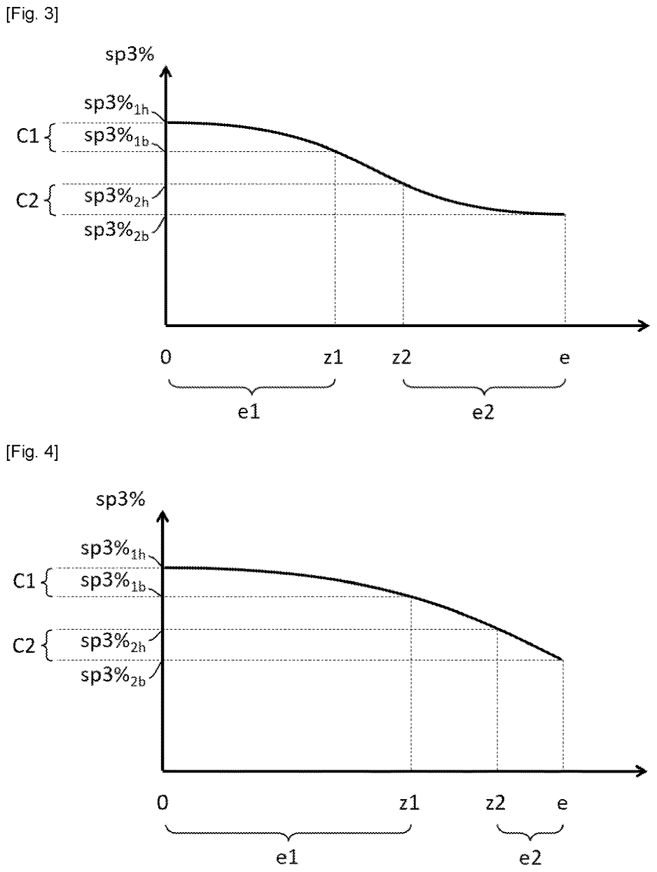

FIG. 3 illustrates a second example in which the sp3 bond content decreases irregularly, but with a first plateau at the start of deposition and a second plateau at the end of deposition. These steps can be obtained by momentarily stopping the variation in the influencing parameter. The first zone (e1) and the second zone (e2) are of equal thickness because the two plateaus are of equivalent lengths, but their thicknesses are greater than in the example in FIG. 2. In contrast, the thickness of the intermediate zone is less than that of the first example.

FIG. 4 illustrates a third example in which the sp3 bond content decreases irregularly, with just one first plateau at the start of deposition. The first zone (e1) is then thicker than the second zone (e2).

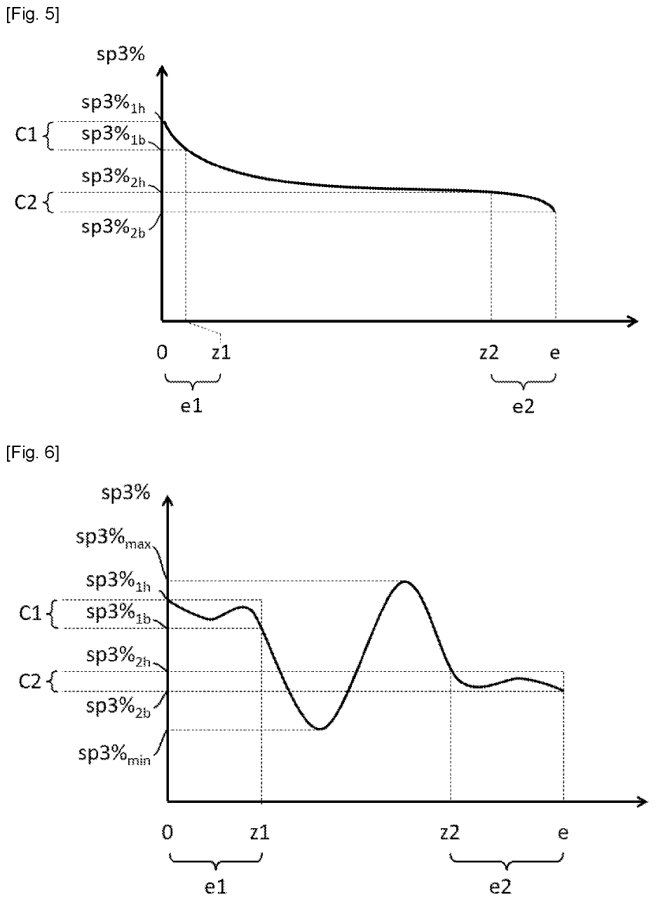

FIG. 5 illustrates a fourth example in which the intermediate zone constitutes the predominant share of the layer (C), because the first zone (e1) and the second zone (e2) are of low thickness, of the order of a few nanometers, for example between 1 nm and 15 nm, or between 5 nm and 10 nm.

FIG. 6 illustrates a fifth example in which the content evolves in a not strictly decreasing manner: variations in the influencing parameter lead to oscillations in the sp3 bond content. Nevertheless, the second sp3 bond content (sp3% 2b) is strictly lower than the first sp3 bond content (sp3% 1h), such that the layer (C) has a first zone (e1) and a second zone (e2). It is possible to obtain an intermediate zone constituting the predominant share of the layer (C), on the basis of the downward trend in the sp3 bond content, and on the basis of the amplitude of the oscillations. The first zone (e1) and the second zone (e2) may be of low thickness, of the order of a few nanometres, for example between 1 nm and 20 nm, or between 5 nm and 10 nm.

The intermediate zone is a zone providing a transition between the first zone (e1) and the second zone (e2). It preferably comprises a limited average sp3 bond content in order to maintain low overall resistivity of the layer. For example, the average content of sp3 bonds within the intermediate layer is less than 40% and preferably less than 25%. Nevertheless, the first sp3 bond content (sp3% 1h) is preferably at least 30% to 40% in order to protect the substrate from oxidation.

The second sp3 bond content (sp3% 2b) is preferably at most 5% to 25%, in order to ensure the good surface conductivity of the part (P).

It is therefore possible to favour one composition over the other by adapting the thickness of the first zone (e1) relative to that of the second zone (e2).

The first sp3 bond content (sp3% 1h) is between 30% and 85%, or between 35% and 80%, or between 40% and 75%, or between 45% and 60%, or between 50% and 65%, or in any range obtained by combining these values.

The second sp3 bond content (sp3% 2b) is chosen to be less than the first content (sp3% 1h) and is between 3% and 70%, or between 15% and 65%, or between 20% and 60%, or between 25% and 55%, or between 50% and 45%, or between 35% and 45%, or in any range obtained by combining these values.

The ratio of the second content (sp3% 2b) to the first content (sp3% 1h) is between 0.05 and 1 (1 excluded) or between 0.2 and 0.9, or between 0.3 and 0.8, or between 0.4 and 0.7, or between 0.5 and 0.6, or in any range obtained by combining these values.

The average sp3 bond content of the layer, i.e. the average value of the content over the entire thickness of the layer, is between 5% and 65%, or between 10% and 60%, or between 15% and 55%, or between 20% and 50%, or between 25% and 40%, or between 30% and 35%, and is for example 9%, or 15%, or 19%, or 22%, or 45%, or 56%, or is within any range obtained by combining these values.

On the basis of the choice of the first content (sp3% 1h) and the second content (sp3% 2b), it is possible to obtain:
a layer (C) of amorphous carbon of type a-C, with a first sp3 content of less than approximately 40%;
a layer (C) of amorphous carbon of the ta-C type, with a second sp3 content of greater than approximately 60%;
a layer (C) of carbon having:
a first zone (e1) rich in sp3 bonds, with a first content (sp3% 1h) of greater than approximately 40%; and
a second zone (e2) rich in sp2 bonds, with a second content (sp3% 2b) of less than approximately 40%.

In one particular embodiment, taken in isolation from the features underlying the invention, or in combination, the energy of the ions is sufficiently high that, at the interface (I) between the layer (C) and the support material receiving it (whether that is the substrate(S) or the underlayer (SC)), carbon is implanted within this material.

Implantation occurs over a thickness of the order of 1 nm to 3 nm, for example 1.5 nm to 2 nm or 2.5 nm.

These carbon implantations make it possible to promote the adhesion of the layer (C).

In this embodiment, the invention makes it possible to facilitate the production of a part (P) with a layer (C) having both good electrical and electrochemical performance, and good adhesion to the part (P), because the adjustment of the energy level is configured both for implanting carbon in the part (P) and for depositing carbon in the form of an sp3 bond.

The performance of a part (P) corresponding to the invention was compared to that of devices of the prior art.

In this embodiment, the part (P) consists of a substrate(S) made of 316L, a 50 nm-thick titanium underlayer (SC), and a 70 nm-thick layer (C) of carbon deposited by cathodic arc, within which the sp3 hybridised bond content decreases in a direction from the substrate(S) towards the external surface (SE).

The layer (C) of carbon does not comprise dopants or nitrogenous elements, in order to avoid the presence of preferential corrosion sites. In contrast, the presence of oxygen within the layer (C) is not a decisive criterion.

The comparative samples are:
comparative sample 1 (EC1): a part consisting of a substrate(S) made of 316L, a 50 nm-thick titanium underlayer (SC), and a 70 nm-thick carbon layer not corresponding to the invention;
comparative sample 2 (EC2): a substrate made of 316L without coating;
comparative sample 3 (EC3): a substrate made of titanium without coating.

Corrosion tests at a potential of +1.6 V/NHE were performed.

With reference to FIG. 6, the current density of the part (P) according to the invention drops rapidly and is less than 200 nA/cm² at the end of the test, i.e. a value comparable to that of the bare titanium substrate (EC3). The coating is still present, unlike that of comparative sample 1 (EC1), the carbon layer (C) of which has been consumed. At the end of this more stringent test, the ICR of the part (P) is low, which is not the case for the bare titanium.

The part (P) according to the invention therefore has both very good conductivity (low ICR) and very good resistance to oxidation (low corrosion current, no consumption of the layer (C)).

Other corrosion tests at a potential of +1.6 V/NHE were performed.

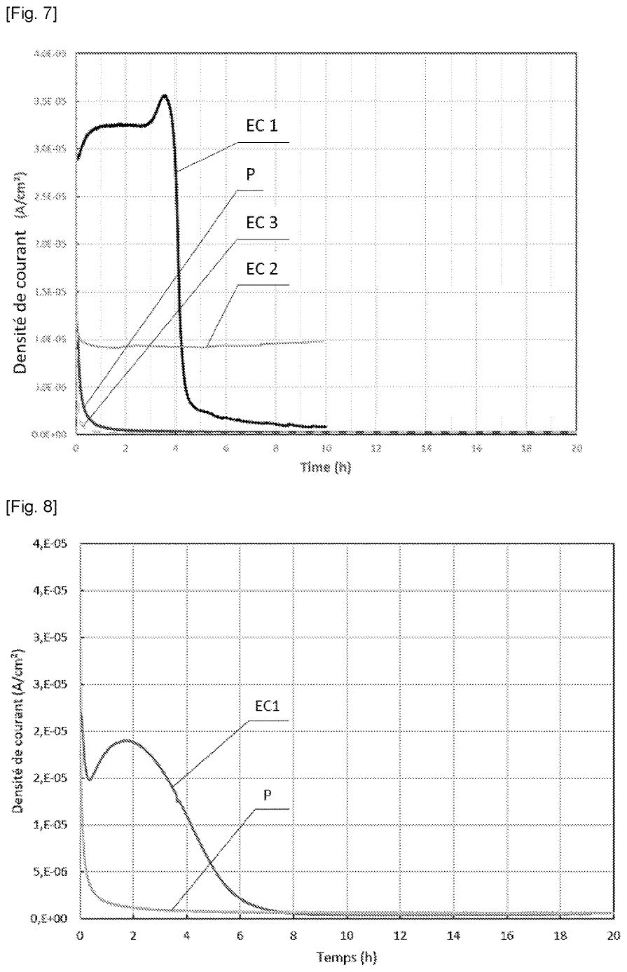

With reference to FIG. 7, the corrosion resistance of a part (P) according to the invention was compared to the comparative sample 1 (EC1).

The characteristics of the sp3 content according to the invention have an impact on the resistance at high potential of the layer (C):
the layer (C) of the part (P) is not consumed, and the corrosion current density is very low;
the comparative sample 1 (EC1) has a low final corrosion current, but the carbon layer (C) is entirely consumed and the metal underlayer (SC) is exposed on the surface (which corresponds to the observation of a greater corrosion current between 0 h and 6 h).

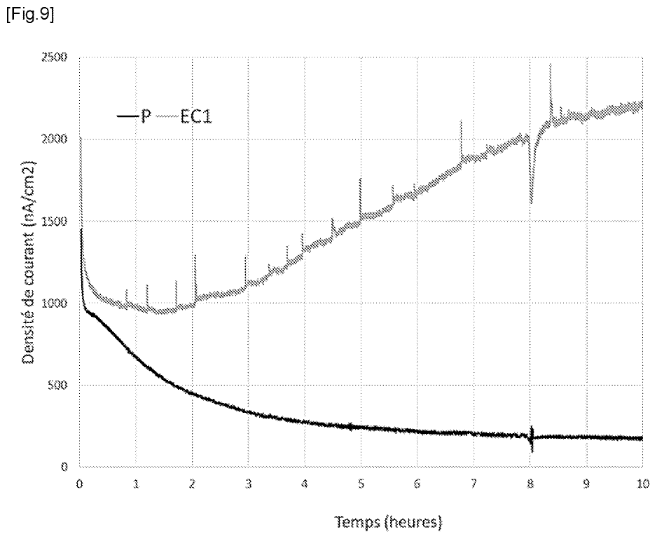

With reference to FIG. 9, another corrosion resistance test is conducted, this time at a potential of 1.2 V/NHE for 10 h and at a temperature of 90° C.

At the end of this other, more stringent, test, it is again observed that the part (P) according to the invention has better resistance to corrosion (only approximately 10 mΩ·cm²) than the comparative sample (EC1) (more than 100 mΩ·cm²).

Those skilled in the art will know how to adapt the deposition parameters, and in particular the influencing parameter, with a view to causing the proportion of sp3 hybridised atoms relative to the sp2 hybridised atoms to continuously evolve, and thus to comply with the invention.

It is recalled that the invention has the advantage of conferring greater durability on the parts (P), in particular at higher temperature and at higher potential (which are two more stringent conditions compared to the standard conditions as described by the DOE), compared to the solutions of the prior art of proton exchange membrane fuel cells.

Moreover, the part (P) can be shaped differently from the examples given without departing from the scope of the invention, which is defined by the claims.

In some embodiments, the part (P) has a stack of a plurality of underlayers (SC) arranged between the substrate(S) and the external layer (C) of carbon-based material.

The carbon layer (C) is described as being external because it is the layer (C) which is intended to be in contact with the electrochemical medium of the cell, and has to both ensure the protection of the part (P) against corrosion and promote electrical conduction. This terminology does not exclude the presence of an additional thin layer of carbon, for example of the a-C or a-C: H type, deposited on top of the carbon layer (C).

The sp3 bond content within the layer (C) may have other profiles than those illustrated.

Furthermore, the technical characteristics of the various embodiments and variants mentioned above can be entirely or partially combined. Thus, the part (P) can be adapted in terms of cost, functionalities and performance.

1. A part comprising a metal substrate and a layer of amorphous carbon-based material having sp2 hybridised bonds and sp3 hybridised bonds, the layer having:
a first content of sp3 hybridised bonds on the substrate side, and
a second content of sp3 hybridised bonds on the side of an external surface of the layer,
the first content being greater than the second content, characterised in that an average content within the layer of sp3 hybridised bonds is between 5% and 65%,
and in that the content of sp3 hybridised bonds evolves continuously within the layer (C).

2. The part according to claim 1, wherein said part comprises a single layer of carbon-based material.

3. The part according to claim 1, wherein the carbon-based material comprises carbon in amorphous form.

4. The part according to claim 1, wherein the carbon-based material is free of dopants.

5. The part according to claim 1, wherein the carbon-based material is free of nitrogen and hydrogen, and even more preferentially free of oxygen.

6. The part according to claim 1, wherein the carbon-based material has an average content of sp3 hybridised bonds of between 10% and 45%.

7. The part according to claim 1, wherein the layer has a thickness of between 20 nm and 250 nm.

8. The part according to claim 1, characterised in that it wherein said part comprises an underlayer which is located between the substrate and the layer of carbon-based material and is in contact with the layer.

9. The part according to claim 8, wherein the material of the underlayer is selected from chromium, titanium, zirconium, tantalum, niobium, or the alloys thereof and the nitrides, nitrocarbides and carbides thereof, or the material of the underlayer is a ceramic.

10. The part according to claim 1, wherein carbon is implanted in a material receiving the layer.

11. A method for the vacuum vapour deposition of a layer of a material based on amorphous carbon on a substrate, wherein a parameter influencing the ratio of sp2 or sp3 hybridised bonds in the carbon varies continuously during the deposition of the layer such that it has:
a first content of sp3 hybridised bonds on the substrate side, and
a second content of sp3 hybridised bonds on the side of an external surface of the layer, which second content is lower than the first content,
and in that an average content within the layer of sp3 hybridised bonds is between 5% and 65%, and preferably between 5% and 45%,
and in that the content of sp3 hybridised bonds evolves continuously within the layer.
